(19) United States
(12) Patent Application Publication
(10) Pub. No.: US 2013/0154025 A1
(43) Pub. Date: Jun. 20, 2013

(54) SEMICONDUCTOR DEVICE INCLUDING CAPACITOR STABILIZING VARIATION OF POWER SUPPLY VOLTAGE

(71) Applicant: Elpida Memory, Inc., Tokyo (JP)

(72) Inventors: Koji YASUMORI, Tokyo (JP); Hisayuki NAGAMINE, Tokyo (JP)

(73) Assignee: Elpida Memory, Inc., Tokyo (JP)

(21) Appl. No.: 13/712,476

(22) Filed: Dec. 12, 2012

(30) Foreign Application Priority Data
Dec. 19, 2011 (JP) 2011-276862

(51) Int. Cl. H01L 29/78; H01L 29/92

(52) U.S. Cl. CPC H01L 29/78; H01L 29/92
USPC 257/379; 257/532

(57) ABSTRACT

Disclosed herein is a semiconductor device that includes a first line supplied with a first voltage, a second line supplied with a second voltage, a first node, at least one first capacitor connected between the first line and the first node, at least one second capacitor connected between the node and the second line, and a protective element connected between the first node and the second line in parallel to the second capacitor.

### FIELD OF THE INVENTION

This application is based upon and claims the benefit of the priority of Japanese patent application No. 2011-276862, filed on Dec. 19, 2011, the disclosure of which is incorporated herein in its entirety by reference thereto.

This present disclosure relates to a semiconductor device and, more particularly, to a semiconductor device having a capacitance element for stabilization that is designed to suppress variations in the power supply voltage.

### DESCRIPTION OF RELATED ART

Recently, the processing speed, required of a semiconductor device, is increasing, while the functions to be implemented by the semiconductor device are being enhanced. As the functions to be implemented by the semiconductor device are being enhanced, the number of the elements to be mounted on board is increasing, with the result that variations in power supply voltages due to parasitic inductances, that is, power supply noises, are becoming problematical. If even a part of the semiconductor devices is destructed due to the variations in the power supply voltages, the semiconductor devices will be felt to be less trustful.

In this consideration, a capacitance element, termed an on-chip capacitor, is provided in the inside of the semiconductor device. The on-chip capacitor is connected between the power supply line and the grounding line to suppress the variations in the power supply voltage. In many cases, a MOS capacitance element, formed in a transistor layer, is used as the on-chip capacitor.

JP Patent Kokai Publication No. JP2000-195254A (Patent Literature 1), which corresponds to U.S. Pat. No. 6,384,674B2 discloses a semiconductor device including a capacitance element aimed to stabilize the power supply. The capacitance element is connected between power supply terminals correlated with an external terminal.

JP Patent Kokai Publication No. JP2007-096036A (Patent literature 2), which corresponds to U.S. Pat. No. 7,602,231B2 discloses a voltage boost circuit composed by a plurality of series connected capacitors aimed to lower the withstand voltage per capacitor.

The disclosures of the above Patent Literatures are incorporated herein in their entirety by reference thereto. The following analysis is given by the present disclosure.

The inventors have realized that, if the techniques disclosed in the above stated Patent Literatures be combined together, there is fear of destruction of a plurality of capacitance elements arranged in series between a VDD power supply line and a VSS power supply line operating as external power supply terminals.

These capacitance elements are disposed in the vicinity of power supply pads in an area where the power supply pads are disposed. This area is referred to below simply as a peripheral area. The reason the capacitance elements are disposed in the peripheral area is that variations in the power supply voltage cannot be suppressed sufficiently unless the elements are disposed in the vicinity of the power supply pads.

On the other hand, the semiconductor device is in need of proper countermeasures against ESD (Electrostatic Discharge) which is a threat to the semiconductor device from outside. As one of such countermeasures, an inter-power-supply protection circuit is arranged between the power supply line and the grounding line. Since the ESD discharge is a high voltage representing a threat to the semiconductor device from outside, the inter-power-supply protection circuit is also provided in the peripheral area.

Hence, the capacitance element to suppress variations of the power supply voltage and the inter-power-supply protection circuit to prevent destruction of internal circuitry due to the ESD discharge are both arranged in the peripheral area. Thus, it may be presupposed that, on occurrence of the ESD discharge, the current not removed by discharging by the inter-power-supply protection circuit flows into the near-by capacitance element. If the current flows into the capacitance element, electrical charges are stored therein. Should ESD discharge occur in succession before the electrical charges thus stored are sufficiently removed by discharging, the withstand voltage of the capacitance element may be exceeded, viz., that an insulation film of the capacitance element may be destroyed by the ESD discharge. The possibility of destruction of the capacitance element by the ESD discharge will be discussed in detail subsequently.

There is a need in the art that, such a semiconductor device in which a capacitance element for stabilization, designed to suppress variations in the power supply voltage, may be prevented from being destroyed by the ESD discharge.

### SUMMARY

In an aspect of this disclosure, there is provided a semiconductor device that includes a first line supplied with a first voltage, a second line supplied with a second voltage, a first node, at least one first capacitor connected between the first line and the first node, at least one second capacitor connected between the node and the second line, and a protective element connected between the first node and the second line in parallel to the second capacitor.

In another aspect of this disclosure, a semiconductor device is provided that includes a first external terminal, a second external terminal, first and second power supply lines, a plurality of capacitance elements, and a PN junction element. The first external terminal is supplied with a first voltage from outside. The second external terminal is supplied with a second voltage lower than the first voltage. The first and second power supply lines respectively are connected to the first and second external terminals. The plurality of capacitance elements are connected in series between the first and second power supply lines. The PN junction element, such as a diode, interconnects a mid connection point that connects different ones of the capacitance elements to each other, and the second power supply line.

In another aspect of this disclosure, there is provided a semiconductor device that includes a first external terminal, a second external terminal, first and second power supply lines, a plurality of capacitance elements, and a semiconductor substrate of a first conductivity type. The first external terminal is supplied with a first voltage from outside. The second external terminal is supplied with a second voltage lower than the first voltage. The first and second power supply lines respectively are connected to the first and second external terminals. The plurality of capacitance elements are connected in series between the first and second power supply lines. A mid connection point interconnecting different ones of the plurality of the capacitance elements to each other is connected to a first area of the second conductivity type which is formed in the semiconductor substrate. The second power supply line is connected to a second area of the first conductivity type which is formed in the semiconductor substrate.

### BRIEF DESCRIPTION OF THE DRAWINGS

FIG. 1 is a circuit diagram schematically showing an Example of the present disclosure.

FIG. 2 is a perspective view showing an example of a longitudinally oriented capacitance element.

FIG. 3 is an example cross-sectional view of the longitudinally oriented capacitance element.

FIG. 4 is a block diagram showing an inner structure of a semiconductor device 1.

FIG. 5 is a plan view showing an example layout of the semiconductor device 1.

FIG. 6 is a diagram showing an example circuit configuration of a second peripheral area 13 of the semiconductor device 1 of Example 2 with its vicinity.

FIG. 7 is an example vertical cross-sectional view taken vertically relative to the substrate through an area where an inter-power-supply protection circuit 18 is formed.

FIG. 8 is a graph showing an example drain current Id versus drain voltage Vd characteristic of the inter-power-supply protection circuit 18.

FIG. 9 is a schematic view for illustrating the withstand voltage in case two capacitance elements are interconnected in series.

FIG. 10 is a schematic view for illustrating the withstand voltage in case three capacitance elements are interconnected in series.

FIG. 11 is a schematic view for illustrating the states of electrical charges in case three capacitance elements are interconnected in series.

FIG. 12 is a plan view showing an example layout of a protective element 21 with its vicinity.

FIG. 13 is a cross-sectional view taken along a line indicated by arrows A-A in FIG. 12.

FIG. 14 is a graph showing an example diode characteristic.

FIG. 15 is a diagram showing an example circuit configuration of a second peripheral area 13 of the semiconductor device 2 of Example 3 with its vicinity.

FIG. 16 is a plan view showing an example layout of a diode element 22 with its vicinity.

FIG. 17 is a cross-sectional view taken along a line indicated by arrows B-B in FIG.16.

FIG. 18 is a diagram showing an example circuit configuration of a second peripheral area 13 of a semiconductor device 3 of Example 4 with its vicinity.

FIG. 19 is an example cross-sectional view of a semiconductor device 4 according to Example 5.

FIG. 20 is a circuit diagram showing the entire configuration of a semiconductor device 5 according to Example 6.

### PREFERRED EXAMPLES

The disclosure will be now described herein with reference to illustrative exemplary embodiments. Those skilled in the art will recognize that many alternative exemplary embodiments can be accomplished using the teachings of the present disclosure and that the disclosure is not limited to the exemplary embodiments illustrated for explanatory purposes.

### Example 1

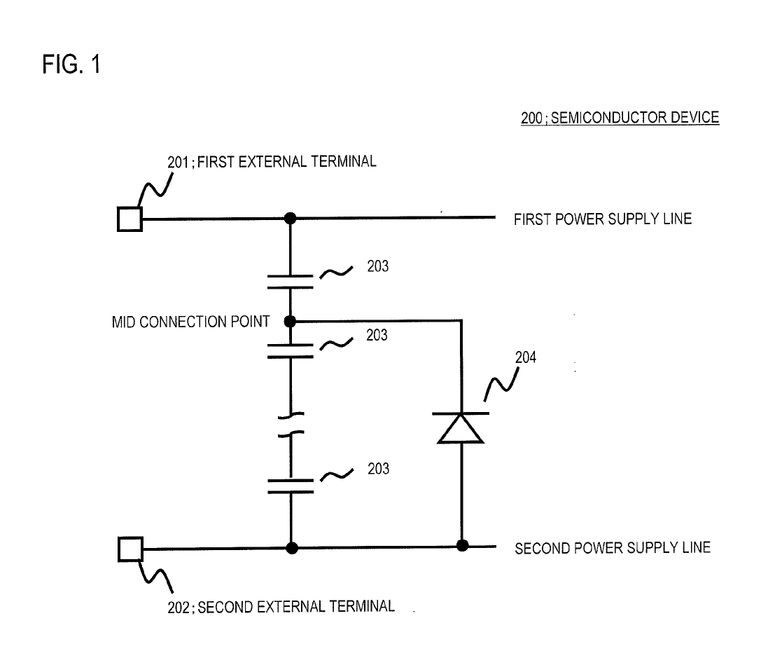

Referring now to FIG. 1, a semiconductor device 200 according to an example embodiment of the present invention includes a first external terminal 201, to which a first voltage is supplied from outside, and a second external terminal 202, to which a second voltage lower than the first voltage is supplied. The semiconductor device also includes a first power supply line and a second power supply line respectively connected to the first external terminal 201 and the second external terminal 202. The semiconductor device further includes a plurality of capacitance elements (or capacitors) 203 connected in series between the first and second power supply lines, and a diode 204 connected between a mid connection point (or a node) and the second power supply line. The mid connection point connects different ones of the capacitance elements 203 to each other. A protective element 204 or a PN junction element is provided and connected between the mid connection point and the second power supply line. In this example, a diode may be used as the protective element 204. The power supply voltage and the grounding voltage are assumed to be the first voltage and the second voltage, respectively.

The diode 204, which is connected to the mid connection point between different ones of the capacitance elements 203, creates a discharge path for the electrical charges stored in the capacitance elements 203. By so doing, electrical charges may not be stored in an amount exceeding the withstand voltage of the capacitance elements 203, thereby preventing destruction of the capacitance elements 203.

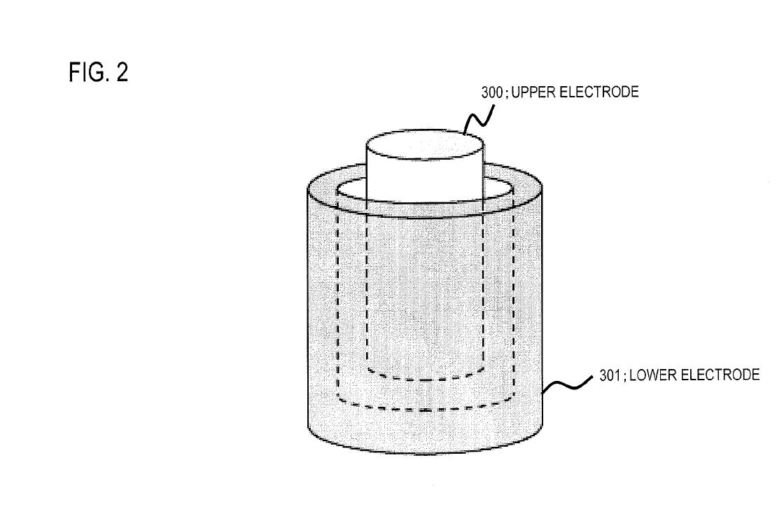

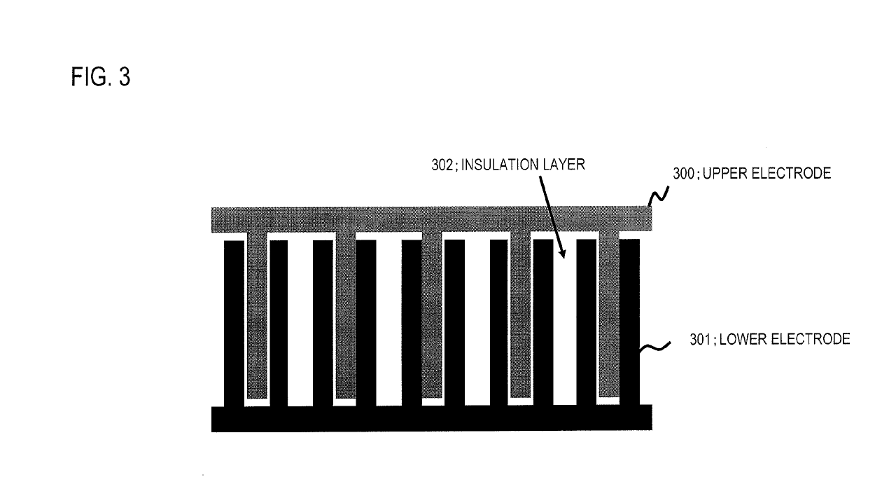

There are cases where the capacitance elements having a longitudinally oriented structure are used in the inside of the semiconductor device. The term “longitudinally” used herein refers to a longitudinal direction of the axis at tubular shape, or traverse to the plane. FIG. 2 depicts a perspective view showing an example capacitance element having such longitudinally oriented structure, and FIG. 3 depicts an example cross-sectional view of the capacitance elements of the longitudinally oriented structure. The capacitance element of the longitudinally oriented structure is such capacitance element in which a pillar or columnar (or cylindrically)-shaped upper electrode 300 is housed within a tubular-shaped lower electrode 301. Referring to FIGS. 2 and 3, a plurality of tubular-shaped capacitance elements are three-dimensionally arranged in the semiconductor device. The integration ratio of the capacitance elements of the longitudinally oriented structure is high, so that, by accommodating the large-capacity capacitance elements within a limited spacing, it is possible to reduce the chip size of the semiconductor device as well as to achieve cost reduction. Hence, the capacitance elements of the longitudinally oriented structure may be used to advantage as the capacitance element 203.

### Example 2

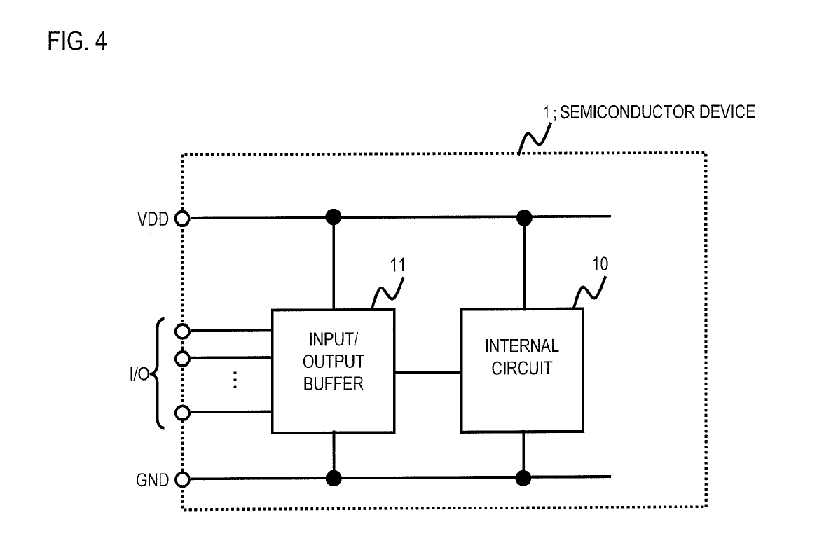

Turning to FIG. 4 depicting a block diagram showing an example of the present invention, an internal circuit 10 of the semiconductor device 1 generates a signal to be output to outside, while performing processing based on a signal received from outside. The communication with an external circuit is then via an I/O terminal (input/output terminal) and via an input/output buffer 11.

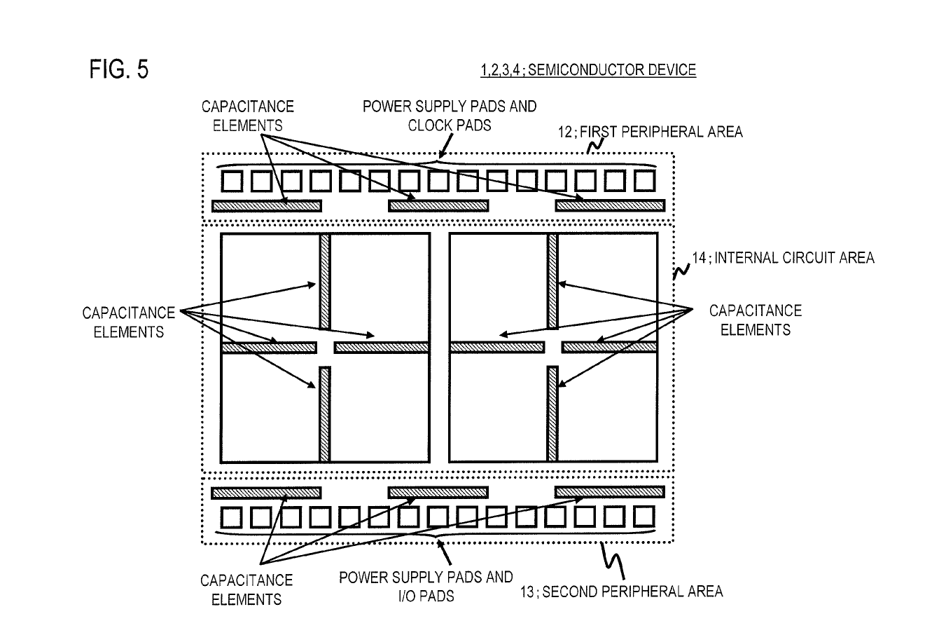

FIG. 5 depicts an example layout of the semiconductor device 1.

In a first peripheral area 12, power supply pads and clock pads are laid out. In a second peripheral area 13, power supply pads and I/O pads are also laid out. In an internal circuit area 14 of the semiconductor device 1, a circuit that processes signals received from outside and the like (part of the internal circuit 10) is laid out.

In the first peripheral area 12, the second peripheral area 13 and in the internal circuit area 14, there are formed capacitance elements (or capacitors) for stabilizing variations of power supply voltages. The capacitance elements disposed in the first peripheral area 12 and in the second peripheral area 13 are connected between the power supply interconnects and the grounding interconnects.

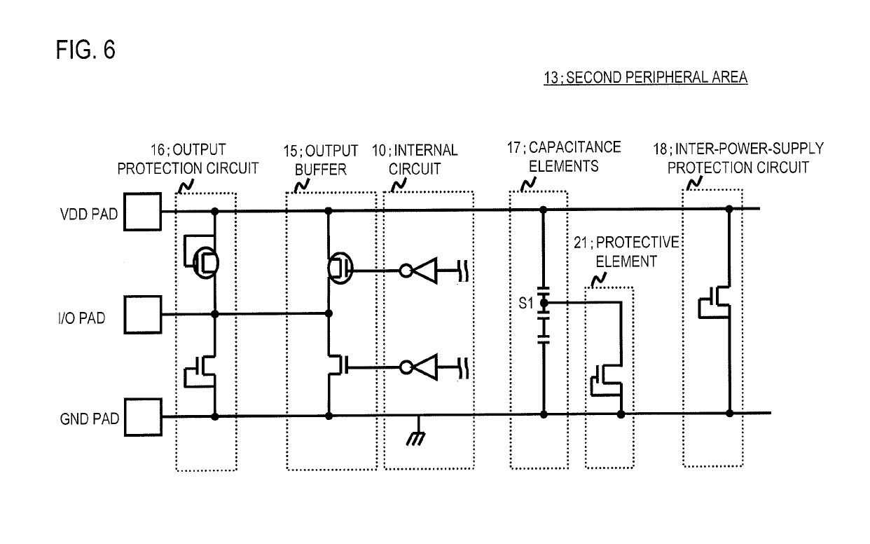

FIG. 6 shows an example circuit configuration of the second peripheral area 13 of the semiconductor device 1 with its vicinity.

Referring to FIG. 6, the semiconductor device 1 outputs a signal, generated by the internal circuit 10, to outside via an output buffer 15 and the I/O pads. An output protection circuit 16 is provided between the pads and the output buffer 15. In the second peripheral area 13, there are provided a capacitance element 17, aimed to suppress variations in the power supply voltage, and an inter-power-supply protection circuit 18. A protective element 21 has its one end connected to a mid connection point S1 of the capacitance element 17, while having its other end grounded. In this example, the capacitive element 17 includes three capacitors connected in series between the VDD and GND power voltage lines. The protective element 21 is connected between the GND power line and the connection node S1 of the first and second capacitors.

It is observed that some countermeasures need to be taken in order to protect the semiconductor device 1 against ESD discharge which is a threat to the semiconductor device from outside. The circuit provided as such countermeasures against the ESD discharge is the inter-power-supply protection circuit 18.

The inter-power-supply protection circuit 18 will now be globally explained.

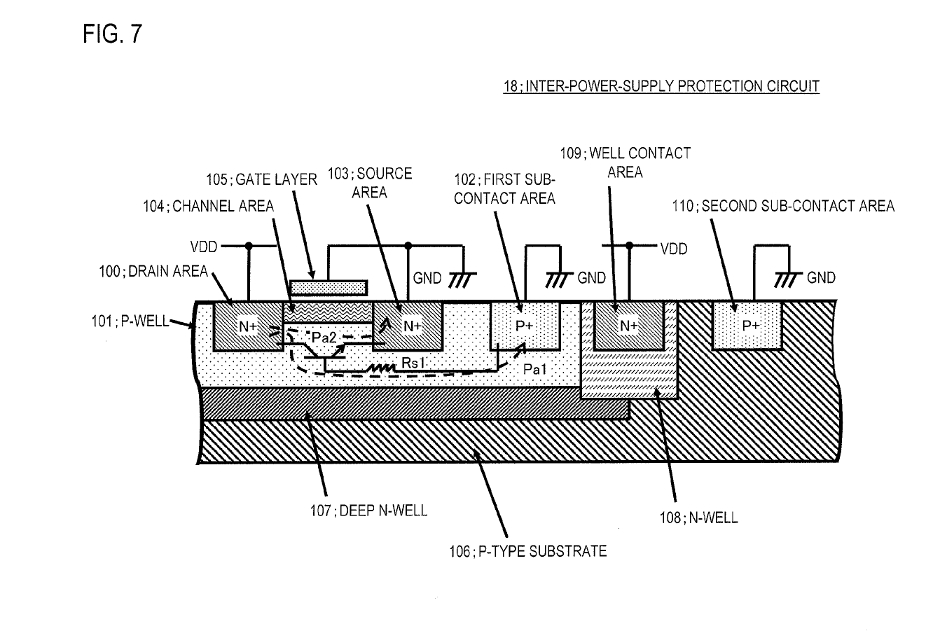

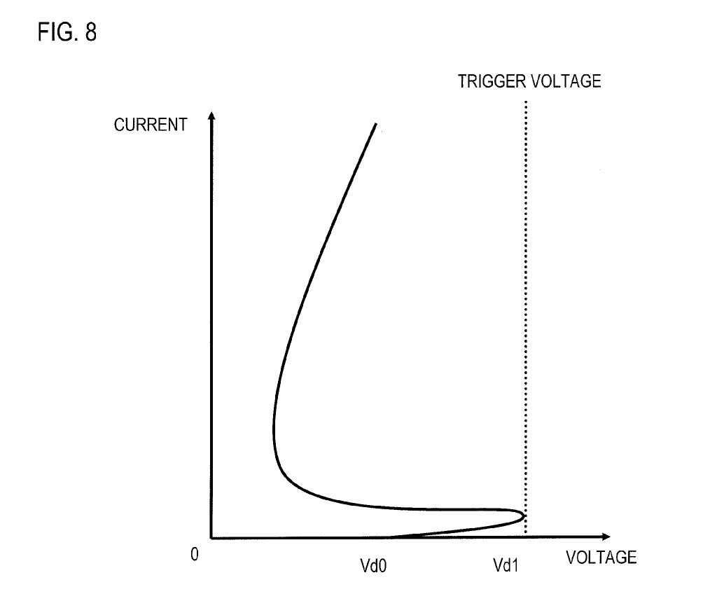

FIG. 7 depicts an example cross-sectional view taken to pass vertically through the area of the inter-power-supply protection circuit 18 with respect to the semiconductor substrate. FIG. 8 depicts a graph showing an example drain current Id versus drain voltage Vd characteristic of the inter-power-supply protection circuit 18.

When a voltage is applied to the power supply VDD, connected to a drain area 100, formed by an N+ diffusion layer, the drain voltage increases. When this drain voltage reaches Vd0 shown in FIG. 8, current flows via a P-well 101 to a first sub-contact area 102 formed by a P+ diffusion layer. In FIG. 7, this current path is indicated by a path Pa1.

Thereafter, the voltage in the vicinity of a source area 103 formed by the N+ diffusion layer rises due to current flowing through the path Pa1 and a parasitic resistance Rs1 in the P-well 101. If then the voltage between the P-well 101 and the source area 103 becomes greater than a pre-set value, the PN junction between the P-well 101 and the source area 103 is forwardly biased to form a low resistance current path from the drain area 100 to the source area 103. In FIG. 7, the low resistance current path is denoted as path Pa2.

Such phenomenon is termed snapback. A trigger voltage at which the snapback starts is a voltage Vd1 shown in FIG. 8. When the snapback occurs in the inter-power-supply protection circuit 18, the current flowing from the power supply VDD is discharged via the source area 103 to the grounding potential GND to suppress excess current from flowing in the internal circuit 10. In this manner, the inter-power-supply protection circuit 18 operates to prevent the internal circuit 10 from being destroyed by the ESD discharge.

Since the ESD discharge is a high voltage representing a threat to the semiconductor device 1 from outside, it has so far been sufficient if countermeasures are taken against the ESD discharge in just the circuitry laid out in the vicinity of the pads of the semiconductor device 1. However, there is a fear that, if a capacitance element is used to suppress variations of the power supply voltage, the capacitance element is destroyed by ESD discharge.

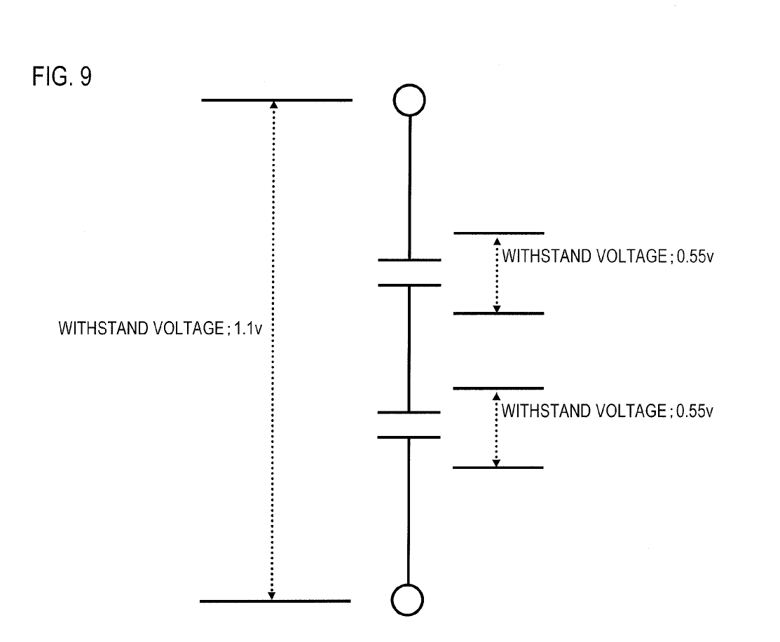

FIG. 9 shows the withstand voltage in case two capacitance elements (capacitors) that are connected in series with each other.

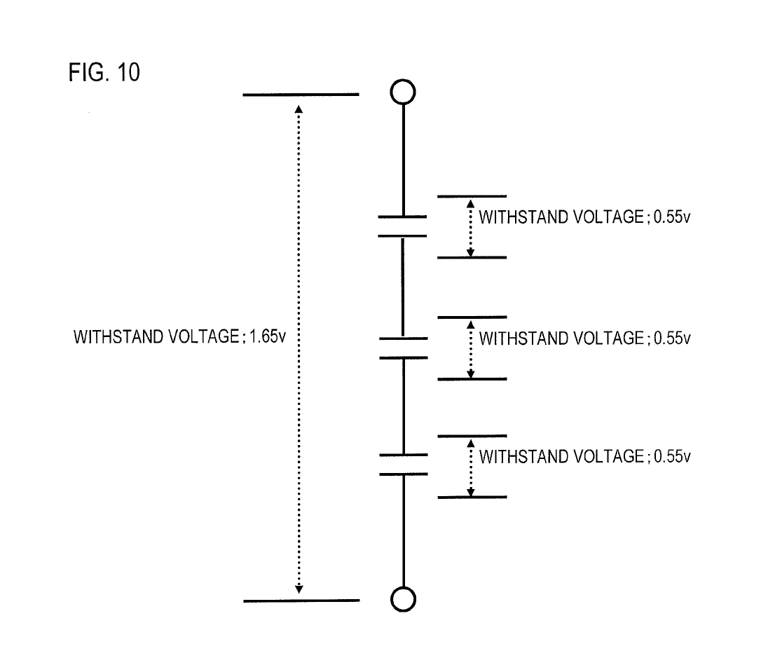

There is a limit to the withstand voltage of the capacitance element. For example, if the withstand voltage per capacitance element, schematically shown in FIG. 9, is 0.55 v, a withstand voltage of 1.1 v may be obtained as the withstand voltage of the capacitance elements in their entirety. However, should a withstand voltage greater than 1.1 v be desired, it is necessary to use three series-connected capacitance elements (capacitors), as shown in FIG. 10. Note, however, voltage volumes mentioned herein are merely by way of example, not limitative intended.

If a plurality of capacitance elements are connected in series in this manner to elevate the withstand voltage of the capacitance elements in their entirety, destruction of the capacitance elements may still take place in case the voltage applied exceeds the withstand voltage due to variations in the external voltage caused by the ESD discharge. In short, if the ESD discharge should take place, the inter-power-supply protection circuit 18 is set into operation. However, the low resistance current path is not formed until the voltage applied reaches the trigger voltage (Vd1 shown in FIG. 8). There is a possibility that, in case electrical charges are stored due to charging in the capacitance elements before the applied voltage reaches the trigger voltage, and the ESD discharge occurs a second time before the stored charged are removed sufficiently by discharging, the insulation film of the capacitance element is destroyed.

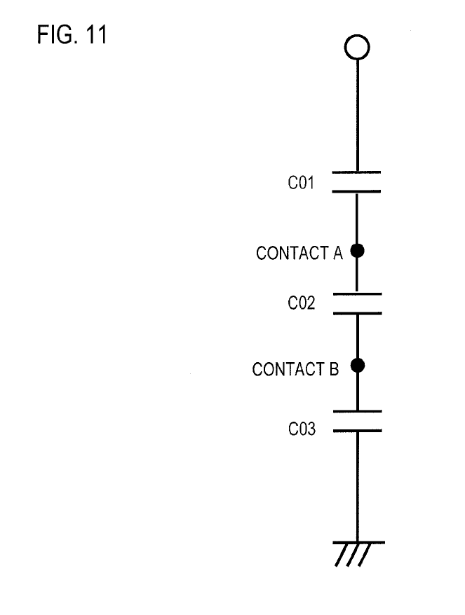

FIG. 11 illustrates the state of electrical charges in case three capacitance elements C01 to C03 are connected in series one with another. Referring to FIG. 11, if the ESD discharge occurs over and over again, the current that has not been discharged in the inter-power-supply protection circuit 18 will flow into the capacitance elements so as to be charged therein. While a connection point B represents a connection point at which the electrical charges at a connection point A are removed by discharging, there is no path via which positive charges stored on the connection point B side of the capacitance element C03 are removed by discharging. Hence, electrical charges are stored in the respective capacitance elements each time the ESD discharge occurs. The insulating film of the capacitance element would be destroyed if the electrical charges stored in the capacitance element exceeds its withstand voltage.

As discussed above, the capacitance elements, aimed to suppress variations in the power supply voltage, are laid out in the vicinity of power supply pads in the first peripheral area 12 and the second peripheral area 13. Thus, the current, which has not been discharged by the inter-power-supply protection circuit 18, is more ready to flow into the capacitance element. There is thus a fear that the electrical charges are stored in the capacitance element to exceed its withstand voltage, thus destructing its insulation film.

In the semiconductor device 1 of the subject Example, the protective element 21 is connected to the mid connection point S1 of the capacitance element 17 to create a path via which the electrical charges stored at the mid connection point S1 are removed by discharging. As a result, the capacitance element may be prevented from being destroyed due to ESD discharge.

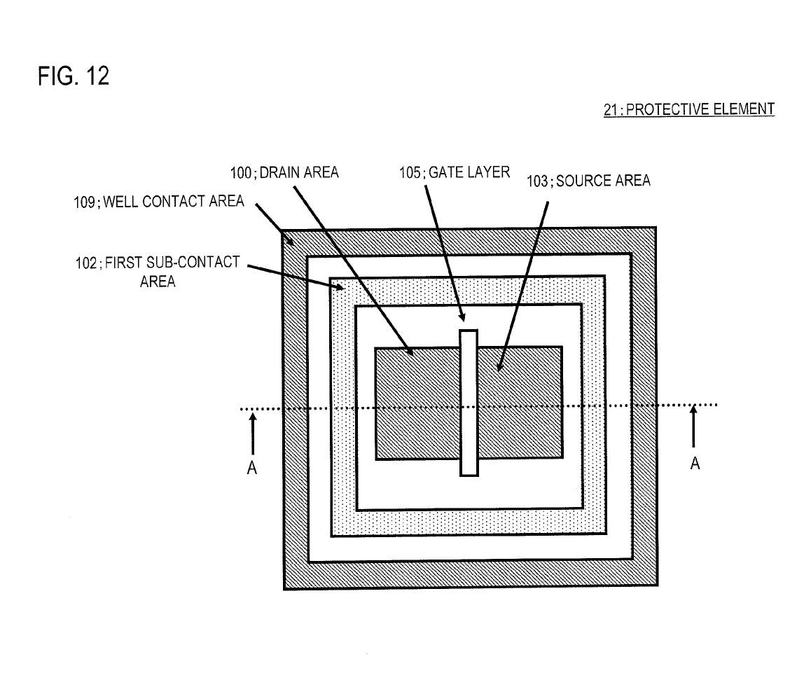

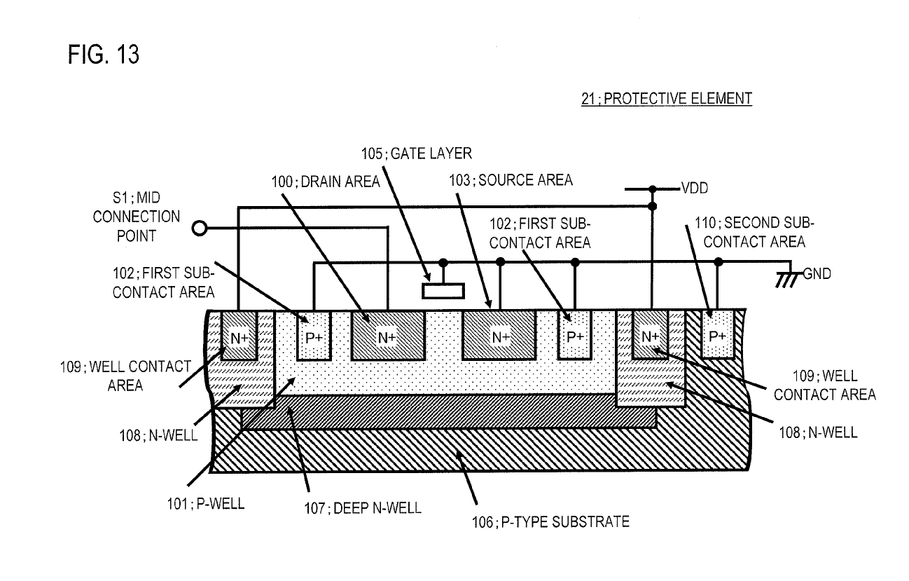

FIG. 12 is a plan view showing an example layout of the protective element 21 with its vicinity. FIG. 13 is a cross-sectional view taken along line A-A in FIG. 12. The component elements of FIG. 13, which are the same as those of FIGS. 7 and 12, are indicated by the same reference signs, and the corresponding description is dispensed with.

The drain area 100 of the protective element 21, shown in FIG. 13, is connected to the mid connection point S1 of the capacitance element 17. Hence, the electrical charges stored at the mid connection point S1 are removed by discharging to the grounding potential GND via the first sub-contact area 102 composed by the P-well 101 and the first sub-contact area 102 formed by a P+ diffusion layer.

As discussed above, the electrical charges, which should otherwise be stored in the capacitance element 17 by the ESD discharge occurring over and over again, can now be removed by discharging to the grounding potential GND as a result of addition of the protective element 21. It is thus possible to prevent destruction of the capacitance element 17.

Moreover, by addition of the protective element 21, it becomes possible to prevent destruction of the internal circuit 10 ascribable to the ESD discharge. But for the protective element 21, a high voltage would be applied across both ends of the inter-power-supply protection circuit 18 due to electrical charges stored in the capacitance element 17. The diode characteristic of the inter-power-supply protection circuit 18 is shifted as a result of application of the high voltage across both ends of the inter-power-supply protection circuit 18.

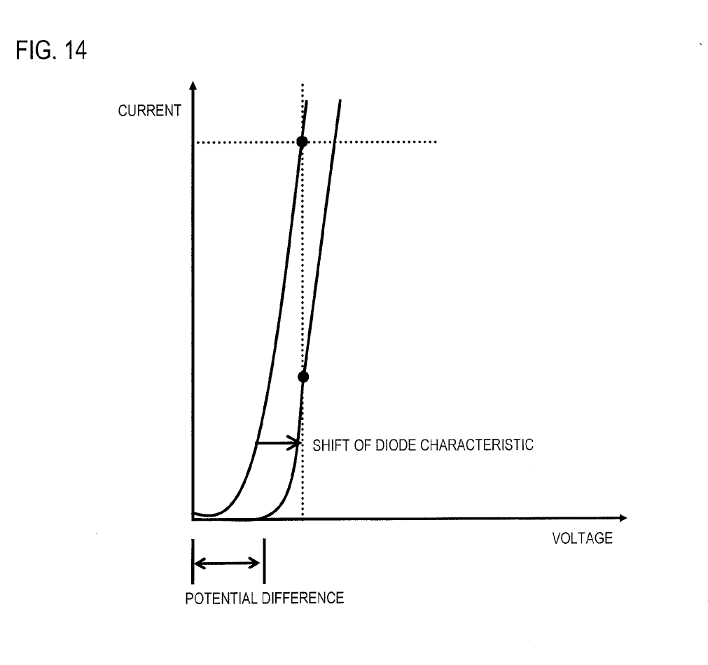

FIG. 14 shows an example diode characteristic. It is seen from FIG. 14 that, if the diode characteristic is shifted, the capability to cause the current to flow is lowered even if the voltage applied to the diode remains the same. This is indicative of deterioration of the discharge capability in the inter-power-supply protection circuit 18, and is tantamount to the decreased current delivered via the inter-power-supply protection circuit 18 to the grounding potential GND. Hence, the current that has not been discharged by the inter-power-supply protection circuit 18 flows into the internal circuit 10 to lead to its destruction. For example, the current that has not been discharged by the inter-power-supply protection circuit 18 flows into the output buffer 15, thus possibly destructing the output buffer. Or, the current that has not been discharged by the inter-power-supply protection circuit 18 flows into the input buffer, thus possibly destructing the output buffer.

It is observed that, by providing the transistors used in the output buffer 15 or in the input buffer with proper countermeasures against the ESD discharge, it is possible to protect the buffers against the ESD discharge. Among possible countermeasures to be taken against the ESD discharge, it may be envisaged to enlarge the distance between the gate electrode and the contact connecting to the diffusion layer. However, in a transistor provided with these countermeasures against the ESD discharge, the gate-to-contact distance becomes larger, thus increasing the element area. Thus, from the perspective of reducing the element area, such countermeasures against the ESD discharge that do not shift the diode characteristic of the inter-power-supply protection circuit 18 are preferred to the above stated countermeasures that will increase the element area.

As discussed above, the electrical charges, stored by charging in the capacitance element, may be removed by discharging to the grounding potential GND, by providing a discharge path connecting from the mid connection point of the capacitance element to the grounding potential. Thus, it becomes possible to prevent the capacitance element from being destroyed to the ESD discharge.

### Example 3

An Example 3 will now be explained with reference to the drawings.

In the subject Example, an example case of providing a discharge path in the capacitance element 17 will be explained.

In the Example 2, an example case of providing the discharge path by the protective element 21 connected to the mid connection point S1 in the capacitance element 17 has been explained. It should be noted that the element thus connected to the mid connection point S1 in the capacitance element 17 may be any element provided that such element forms a discharge path on a substrate.

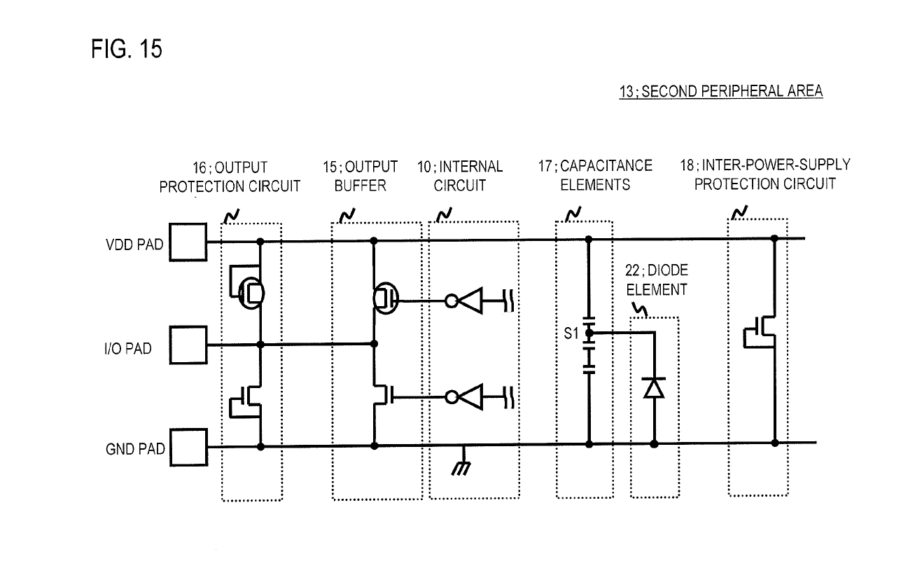

FIG. 15 illustrates an example circuit configuration of the second peripheral area 13 of a semiconductor device 2 of the subject Example with its vicinity. In FIG. 15, the component elements which are the same as those shown in FIG. 6 are denoted by the same reference signs and the corresponding explanation is dispensed with. The point of difference of FIG. 15 from FIG. 6 is that not the protective element 21 but a diode element 22 is connected to the capacitance element 17.

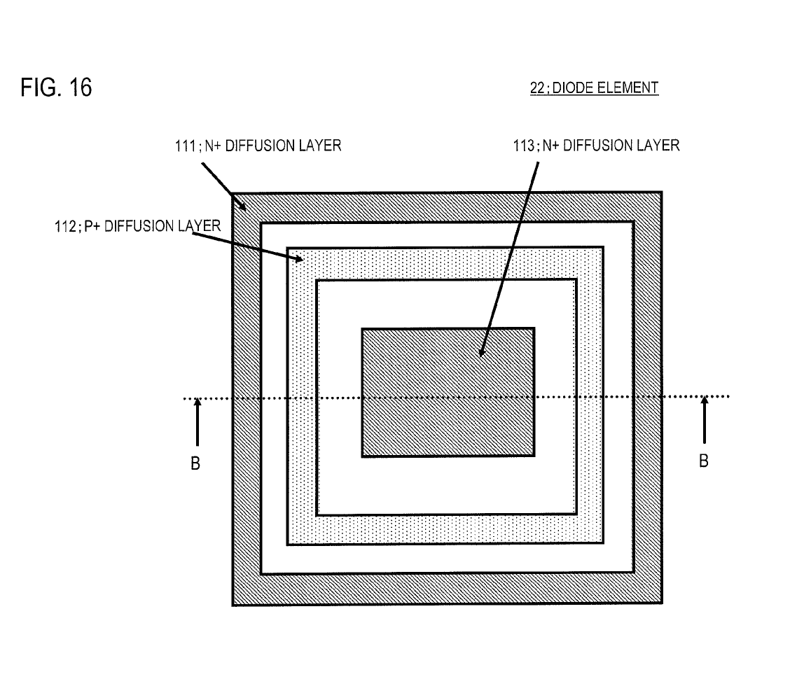

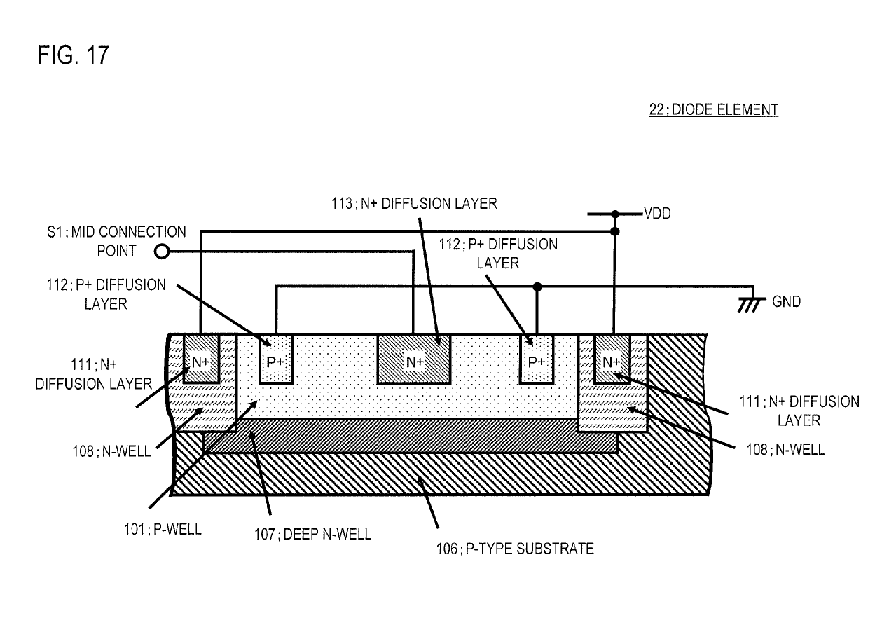

FIG. 16 is a plan view showing an example layout of the diode element 22 with its vicinity. FIG. 17 is a cross-sectional view taken along line B-B of FIG. 16. In FIG. 17, the same reference signs are used to depict the same component elements as those shown in FIG. 16 and the corresponding explanation is dispensed with. In the diode element 22, a deep N-well 107 is layered on a P-type substrate 106. A P-well 101 is connected to the grounding potential GND. An N+ diffusion layer 113 and P+ diffusion layers 112 are formed in the P-well 101. The N+ diffusion layer 113 is connected to the mid connection point S1 of the capacitance element 17, while the P+ diffusion layers 112 is connected to the grounding potential GND. By connecting the diode element 22 to the mid connection point S1 of the capacitance element 17 in this manner, it is again possible to remove, by discharging, the electrical charges stored at the mid connection point of the capacitance element 17.

### Example 4

An Example 4 will now be explained in detail with reference to the drawings. In the subject Example 4, as well, an example case of providing a discharge path for the capacitance element 17 will be explained.

It is not necessarily a single element that is connected to the mid connection point S1 of the capacitance element 17.

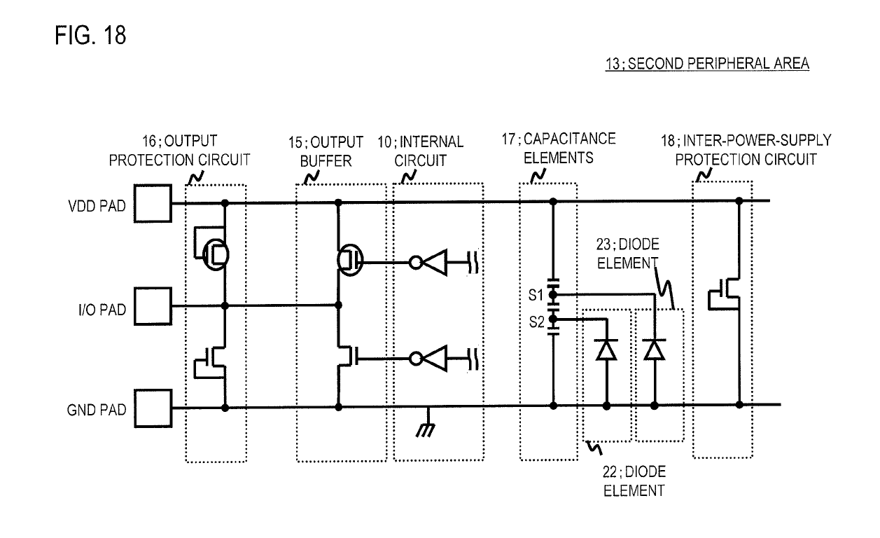

FIG. 18 shows an example circuit configuration of the second peripheral area 13 of a semiconductor device 3 of the subject Example with its vicinity. In FIG. 18, the same reference signs are used to depict the same component parts as those used in FIG. 15.

Two diode elements 22, 23 may be connected to mid connection points S1, S2 of the capacitance element 17, as shown in FIG. 18. A higher discharge effect may be obtained with the connection shown in FIG. 18.

Other than three of the capacitances may be included in the capacitance element 17. It is only sufficient that the capacitance element 17 is formed by a plurality of series-connected capacitances, there being no limitation to the number of the capacitances.

### Example 5

An Example 5 will now be explained in detail with reference to the drawings. In the subject Example as well, an example case of providing a discharge path in the capacitance element 17 will be explained.

It is not mandatory to use a semiconductor device to provide a discharge path from the capacitance element 17 to the substrate.

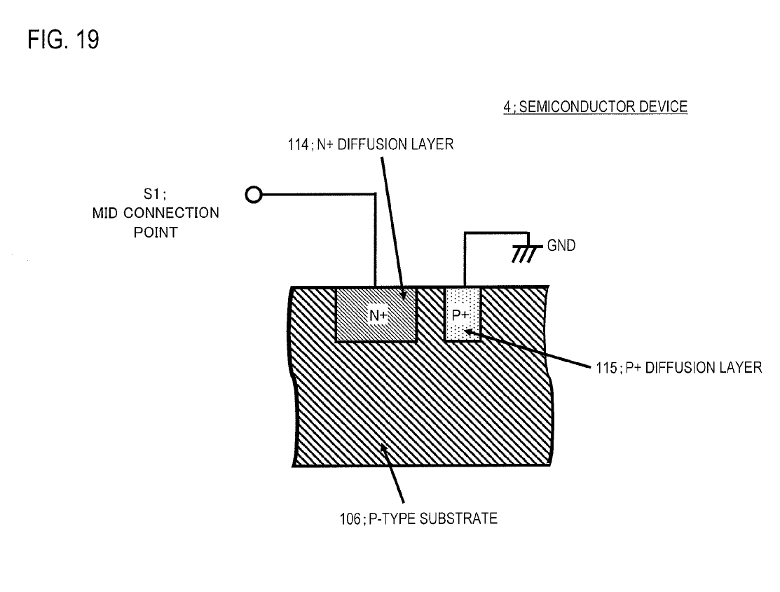

FIG. 19 depicts a schematic example cross-sectional view of a semiconductor device 4 of the subject Example. Referring to FIG. 19, a mid connection point S1 of the capacitance element 17 may be connected to an N+ diffusion layer 114, formed on a P-type substrate 106, such as to provide a discharge path between the N+ diffusion layer 114 and a P+ diffusion layer 115 connected to the grounding potential GND. In such case, the shorter a distance (first distance) between the N+ diffusion layer 114 connected to the mid connection point S1 and the P+ diffusion layer 115 connected to the grounding potential GND, the higher is the discharging capability. Around the N+ diffusion layer 114, a well(s) in which to form other element(s) or a diffusion layer(s) as a well contact to feed the current to the well(s) may be arranged in addition to the P+ diffusion layer 115 connected to the grounding potential GND. It is noted that neither the well(s) in which to form other element(s) nor the diffusion layer(s) are shown. Preferably, the above stated first distance is shorter than the distance between the N+ diffusion layer 114 and the other diffusion layers.

As discussed in connection with the Examples 3 to 5, the discharge path may be provided for the capacitance element 17 in a number of ways. The beneficent results similar to those explained in connection with the Example 2 may be obtained no matter in which manner the discharge path is provided.

### Example 6

An Example 6 will now be explained in detail with reference to the drawings.

In the subject Example, the manner in which, by providing a discharge path from the mid connection point of the capacitance element used in a semiconductor memory to the grounding potential GND, the electrical charges, stored by charging in the capacitance element, may be removed by discharging to the grounding potential, will be explained.

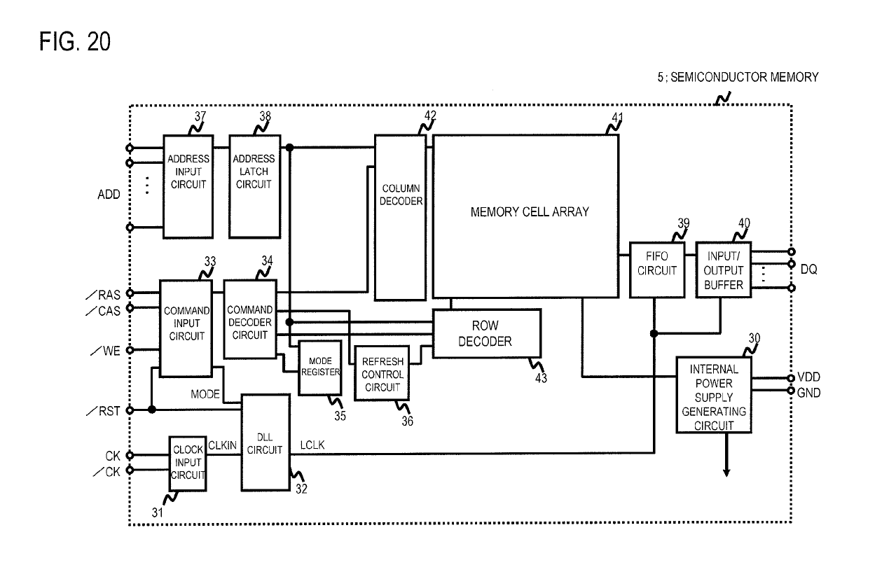

FIG. 20 shows a global configuration of a semiconductor memory 5 of the subject Example. The semiconductor memory 5 includes a number of terminals, including command terminals (/RAS, /CAS, /WE), a reset terminal (/RST), address terminals (ADD), power supply terminals (VDD, VSS), clock terminals (CK, /CK) and data terminals (DQ).

The semiconductor memory 5 also includes an internal power supply generating circuit 30, a clock input circuit 31, a DLL circuit 32, a command input circuit 33, a command decoder circuit 34, a mode register 35, a refresh control circuit 36, an address input circuit 37, an address latch circuit 38, a FIFO circuit 39, an input/output buffer 40, a memory cell array 41, a column decoder 42 and a row decoder 43.

The internal power supply generating circuit 30 generates a voltage used in the peripheral circuit of the semiconductor memory 5, which semiconductor memory receives supply power from outside to generate several voltages in its inside. The clock input circuit 31 accepts differential clocks (CK, /CK) entered from the inner side to output a single phase clock CLKIN. The DLL circuit 32 delays the single phase clock CLKIN to generate an internal clock LCLK.

The commands to the semiconductor memory 5 are accepted via the command terminals by the command input circuit 33. Specifically, the commands composed by a row address strobe signal/RAS, a column address strobe signal/CAS, a write enable signal /WE and so on are entered. The commands, composed by these signals, are decoded by the command decoder circuit 34, and decoded results are output to the mode register 35, the column decoder 42 and to the row decoder 43.

The mode register 35 holds an operating mode of the semiconductor memory 4 determined by a mode register set (MRS) command issued from outside.

On accepting a refresh command from outside, the refresh control circuit 36 controls the refresh operation of the memory cells.

An address signal, issued from outside, is accepted by the address input circuit 37 and latched by the address latch circuit 38. The address signal is delivered to the mode register 35, the column decoder 42 and to the row decoder 43.

The memory cell array 41 holds data. The column decoder 42 and the row decoder 43 decode the address signal to control the access to the memory cell array 41.

During data readout, read data, read out from the selected memory cell, is output at the data terminal DQ via the FIFO circuit 39 and the input/output buffer 40. During the data write operation, write data, entered to the data terminal DQ, is written in the selected memory cell via the input/output buffer 40 and the FIFO circuit 39.

The memory cell array 41 of the semiconductor memory 5 is composed by a plurality of memory cells which perform the role of holding data (storing the information). Each memory cell is made up by a word line, a bit line and a capacitance element arranged at an intersection of the word and bit lines. The states (charging/discharging) of the capacitance element at the intersection of the word and bit lines are made to correspond to data retention (0/1).

In the semiconductor memory 5, as well, it is necessary to suppress variations in the power supplied to the internal circuits, such as the input/output buffer 40. Hence, a capacitance element, aimed to suppress variations in the power supply, is to be arranged, apart from the memory cells, in a peripheral area where there are provided the internal circuits. In this case, a longitudinally oriented capacitance element is frequently used in a semiconductor memory in order to respond to the demand to reduce the memory chip size. The reason is that the longitudinally oriented capacitance elements, in which a plurality of tubular-shaped electrodes is arrayed three-dimensionally, are high in the integration ratio and may provide a solution to the task of reducing the memory chip size. Viz., if the same interlayer insulation film is used for both the capacitance elements used in the memory cells and the longitudinally oriented capacitance elements, the capacitance per unit area of the longitudinally oriented capacitance elements is higher. It is thus felt that the longitudinally oriented capacitance element would be preferentially used in the semiconductor memory.

As discussed above, the capacitance elements, arranged in a peripheral area of the semiconductor memory 5, are thought to be predominantly the longitudinally oriented capacitance elements. In such case, a low withstand voltage of the longitudinally oriented capacitance element, that is, the higher tendency of the longitudinally oriented capacitance elements to be destroyed by the ESD discharge, would be problematical. In the semiconductor memory 5 as well, it is of course necessary to prevent destruction of an internal circuit due to ESD discharge. However, if the longitudinally oriented capacitance elements, which are low in the withstand voltage, are arranged in the peripheral area, it would be necessary to prevent destruction of these elements themselves in view of their low withstand voltage. In particular, since the longitudinally oriented capacitance elements are the capacitances formed between different ones of multilevel interconnects, proper countermeasures must be taken against the ESD discharge of upper level interconnects of the multilevel interconnects.

Hence, a discharge path is provided from the mid connection point of the longitudinally oriented capacitance elements in the semiconductor memory 5 to the grounding potential GND, thereby safeguarding the longitudinally oriented capacitance elements from being destroyed due to ESD discharge. Viz., the countermeasures against the ESD discharge consisting in providing the discharge path to the mid connection point of the longitudinally oriented capacitance elements are most beneficent in the semiconductor memory 5 in which the longitudinally oriented capacitance elements are arranged in its peripheral area.

It is observed that the memory cells of the present Application may be volatile memory cells, non-volatile memory cells or a hybrid of the volatile and non-volatile memory cells. The technical concept of the present Application may be applied to the total of the semiconductor devices including capacitance elements. The circuit format in each circuit block as well as the format of the other control signal generating circuits, disclosed in the drawings, is not limited to the format disclosed in the exemplary embodiments.

The technical concept of the semiconductor device of the present disclosure may be applied to a variety of semiconductor devices. For example, the technical concept of the semiconductor device of the present disclosure may be applied to such semiconductor devices as a CPU (Central Processing Unit), an MCU (Micro Control Unit), a DSP (Digital Signal Processor), an ASIC (Application Specific Integrated Circuit), an ASSP (Application Specific Standard Product) or memories.

The semiconductor devices, to which the present disclosure is applied, may be in the form of, for example, an SOC (system-on-chip), a MCP (multi-chip package) or a POP (package-on-package). The present disclosure may be applied to any of the semiconductor devices having these product or package forms.

It is sufficient for the transistor to be a field-effect transistor (Field Effect Transistor). That is, the present disclosure may be applied to a variety of FETs, namely a MIS (Metal-Insulator Semiconductor) or a TFT (Thin Film Transistor) besides the MOS (Metal Oxide Semiconductor).

Part of the transistors in the device may be bipolar transistors. A PMOS transistor (P channel MOS transistor) and an NMOS transistor (N channel MOS transistor) are representative examples of a transistor of a first conductivity type and a transistor of a second conductivity type, respectively.

The disclosure of the above stated Patent Publications is incorporated by reference herein. The particular exemplary embodiments or examples may be modified or adjusted within the gamut of the entire disclosure, inclusive of claims, based on the fundamental technical concept of the disclosure. Moreover, a variety of combinations or selections of elements disclosed herein, inclusive of elements of the claims, exemplary embodiment or Examples as well as elements of the drawings may be made within the concept of the claims. Viz., the present disclosure may encompass a wide variety of modifications or corrections that may occur to those skilled in the art in accordance with the entire disclosure, inclusive of claim and the technical concept of the present disclosure. For example, the PMOS transistor may include a P+ diffusion layer, in place of the N+ diffusion layer, or a diode formed by a P+ diffusion layer may be used, dependent on the potential of the protective element added. In particular, as regards the ranges of numerical values, set out above, optional numerical values or optional sub-ranges, contained in such ranges, should be interpreted as if they are explicitly stated, even though such optional numerical values or optional sub-ranges are not so stated.

What is claimed is:

1. A semiconductor device comprising:
a first line supplied with a first voltage;
a second line supplied with a second voltage;
a first node;
at least one first capacitor connected between the first line and the first node;
at least one second capacitor connected between the node and the second line; and
a protective element connected between the first node and the second line in parallel to the second capacitor.

2. The semiconductor device according to claim 1, wherein,
the protective element has cathode and anode connected respectively to the first node and the second line.

3. The semiconductor device according to claim 2, wherein the protective element is formed in a semiconductor substrate of a first conductivity type, the cathode being a first diffusion layer of the second conductivity type which is formed in the semiconductor substrate, and the anode being a second diffusion layer of the first conductivity type which is formed in the semiconductor substrate.

4. The semiconductor device according to claim 3, wherein the protective element further includes comprising another diffusion layer of the first conductivity type formed in the semiconductor substrate; and wherein,
the first and second diffusion layers are disposed to each other at a first distance that is less than a distance between the first diffusion layer and the other diffusion layer.

5. The semiconductor device according to claim 3, further comprising:
a third diffusion layer of the first conductivity type which is formed in the semiconductor substrate;
the first and second diffusion layers being formed in the third diffusion layer; the anode being the second and third diffusion layers.

6. The semiconductor device according to claim 5, further comprising:
a fourth diffusion layer of the second conductivity type which is formed in the semiconductor substrate; wherein,
the fourth diffusion layer is between the semiconductor substrate and the third diffusion layer.

7. The semiconductor device according to claim 5, further comprising:
a fifth diffusion layer of the second conductivity type which is formed in the semiconductor substrate; wherein,
the fifth diffusion layer is formed encircling at least the first to third diffusion layers.

8. The semiconductor device according to claim 7, further comprising:
a fourth diffusion layer of the second conductivity type which is formed in the semiconductor substrate; wherein,
the fourth diffusion layer is formed sandwiched between the semiconductor substrate and the third diffusion layer,
the second diffusion layer when seen in a plan view of the semiconductor substrate being formed encircling the first diffusion layer.

9. The semiconductor device according to claim 8, wherein,
the fifth diffusion layer is formed encircling the fourth diffusion layer.

10. The semiconductor device according to claim 1, wherein,
the protective element is a field effect transistor having a gate, a source, a drain and a back-bias;
the mid connection point being connected to the drain; the second line being connected to the gate, the source and the back-bias.

11. The semiconductor device according to claim 10, further comprising:
a semiconductor substrate of the first conductivity type;
a first diffusion layer of the first conductivity type which is formed on the semiconductor substrate;
second and third diffusion layers of the second conductivity type which are formed in the first diffusion layer;
a fourth diffusion layer of the first conductivity type which is formed in the first diffusion layer; and
the gate layer being formed via a gate insulation layer on a surface of the semiconductor substrate;
the drain being the second diffusion layer;
the source being the third diffusion layer;
the back-bias being the first diffusion layer;
the first diffusion layer being connected to the second line via the fourth diffusion layer.

12. The semiconductor device according to claim 11, further comprising:
a fifth diffusion layer of the second conductivity type which is formed in the semiconductor substrate; wherein,
the fifth diffusion layer is formed sandwiched between the semiconductor substrate and the first diffusion layer.

13. The semiconductor device according to claim 11, further comprising:
a sixth diffusion layer of the second conductivity type which is formed in the semiconductor substrate; wherein,
the sixth diffusion layer is formed encircling at least the first to fourth diffusion layers.

14. The semiconductor device according to claim 13, further comprising:
a fifth diffusion layer of the second conductivity type which is formed in the semiconductor substrate; wherein,
the fifth diffusion layer is formed sandwiched between the semiconductor substrate and the first diffusion layer;
the fourth diffusion layer being formed encircling the second diffusion layer.

15. The semiconductor device according to claim 14, wherein,
the sixth diffusion layer is formed encircling the fifth diffusion layer.

16. A semiconductor device, comprising:
a first external terminal supplied with a first voltage from outside;
a second external terminal supplied with a second voltage lower than the first voltage;
first and second power supply lines respectively connected to the first and second external terminals;
a plurality of capacitance elements connected in series between the first and second power supply lines; and
a semiconductor substrate of a first conductivity type; wherein,
a mid connection point interconnecting different ones of the plurality of the capacitance elements to each other is connected to a first area of the second conductivity type which is formed in the semiconductor substrate;
the second power supply line being connected to a second area of the first conductivity type which is formed in the semiconductor substrate.

17. The semiconductor device according to claim 1, wherein,
the plurality of the capacitance elements are longitudinally oriented capacitance elements that are formed between multilevel interconnects and that are of such a structure in which pillar-shaped upper electrodes are housed in tubular shaped lower electrodes, respectively.

18. A semiconductor device comprising:
a first conductive line conveying a first voltage;
a second conductive line conveying a second voltage;
a connection node;
a first capacitor connected between the first conductive line and the connection node;
a second capacitor connected between the connection node and the second line; and
a first element functioning as a diode and connected between the connection node and the second line such that the first element is reverse-biased by a voltage between the connection node and the second line.

19. The device according to claim 18, further comprising a third capacitor inserted between the second capacitor and the second line and a second element functioning as a diode and connected between a connection point of the second and third capacitors and the second line such that the second element is reverse-biased by a voltage between the connection point and the second line.

20. The device according to claim 18, wherein each of the first and second capacitors includes a cylindrical electrode, dielectric film covering the cylindrical electrode and an opposite electrode formed on the dielectric film.
